(19) United States
(12) Patent Application Publication
(10) Pub. No.: US 2013/0161712 A1
(43) Pub. Date: Jun. 27, 2013

(54) SEMICONDUCTOR DEVICE

(71) Applicant: FUJITSU LIMITED, Kawasaki-shi (JP)

(72) Inventors: Hiroko TASHIRO, Ashigarakami (JP); Takeshi ISHITSUKA, Isehara (JP)

(73) Assignee: FUJITSU LIMITED, Kawasaki-shi (JP)

(21) Appl. No.: 13/684,841

(22) Filed: Nov. 26, 2012

(30) Foreign Application Priority Data
Dec. 26, 2011 (JP) 2011-283771

(51) Int. Cl. H01L 27/06

(52) U.S. Cl. CPC H01L 27/0629
USPC 257/296

(57) ABSTRACT

A semiconductor device includes a semiconductor circuit and a capacitor, the capacitor including: a first semiconductor region of a first conductivity type, a second semiconductor region of the first conductivity type, the second semiconductor region being provided on the first semiconductor region of the first conductivity type and having a higher concentration of a first conductivity type impurity than the first semiconductor region of the first conductivity type, a semiconductor region of a second conductivity type provided on the second semiconductor region of the first conductivity type, a dielectric film provided on the semiconductor region of the second conductivity type, an upper electrode provided on the dielectric film, a first interconnection provided above the semiconductor region of the second conductivity type and electrically connected to the semiconductor region of the second conductivity type, and a second interconnection electrically connected to the upper electrode.

### CROSS-REFERENCE TO RELATED APPLICATION

This application is based upon and claims the benefit of priority of the prior Japanese Patent Application No. 2011-283771, filed on Dec. 26, 2011, the entire contents of which are incorporated herein by reference.

### FIELD

The embodiments discussed herein are related to a semiconductor device.

### BACKGROUND

In a semiconductor device, a logic circuit and a complementary metal-oxide semiconductor (CMOS)-containing circuit are each connected to a pair of power lines in order to supply a DC power. A decoupling capacitor is connected in parallel to the pair of power lines. The decoupling capacitor is also referred to as a bypass capacitor and is a capacitor to inhibit voltage fluctuations of the DC power fed to the pair of power lines.

A decoupling capacitor that has been used in the past typically has a metal-oxide-semiconductor (MOS) structure. For example, a structure in which an insulating film is provided on an n-type impurity region arranged on a p-type well in a silicon substrate and in which an upper electrode is provided on the insulating film is known. In this case, it is known that an n-type impurity region is also provided on a side of the upper electrode to equalize impurity concentrations between the n-type impurity region below the upper electrode and the n-type impurity region on the side of the upper electrode.

It is known that a polysilicon film is used as an upper electrode and the polysilicon film is doped with an impurity of a conductivity type the same as that of an n-type impurity region located below the polysilicon film, thereby forming a capacitor having excellent frequency response characteristics.

It is known that a capacitor has a structure formed by preparing a silicon-on-insulator (SOI) substrate with a structure in which a p-type silicon layer having a uniform impurity concentration is provided on an insulating film, implanting a p-type impurity into an upper portion of the p-type silicon layer to increase the concentration, and forming an insulating film and an upper electrode, in that order, on the p-type silicon layer.

The following is a reference document.
[Document 1] Japanese Laid-open Patent Publication No. 2007-157892
[Document 2] Japanese Laid-open Patent Publication No. 2003-347419

### SUMMARY

According to an aspect of the invention, a semiconductor device includes a semiconductor circuit and a capacitor, the capacitor including: a first semiconductor region of a first conductivity type, a second semiconductor region of the first conductivity type, the second semiconductor region being provided on the first semiconductor region of the first conductivity type and having a higher concentration of a first conductivity type impurity than the first semiconductor region of the first conductivity type, a semiconductor region of a second conductivity type provided on the second semiconductor region of the first conductivity type, a dielectric film provided on the semiconductor region of the second conductivity type, an upper electrode provided on the dielectric film, a first interconnection provided above the semiconductor region of the second conductivity type and electrically connected to the semiconductor region of the second conductivity type, and a second interconnection electrically connected to the upper electrode.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are cross-sectional views illustrating a production process of a semiconductor device according to a first embodiment;

FIG. 2 is an equivalent circuit diagram of a semiconductor device according to an embodiment;

FIG. 3 is a characteristic diagram illustrating the relationship between the voltage applied to a capacitor in the semiconductor device according to the first embodiment and the capacitance of the capacitor at different frequencies;

FIG. 4 is a cross-sectional view illustrating a capacitor in a semiconductor device according to a first comparative embodiment;

FIG. 5 is a characteristic diagram illustrating the relationship between the voltage applied to the capacitor in the semiconductor device according to the first comparative embodiment and the capacitance of the capacitor at different frequencies;

FIG. 6 is a cross-sectional view illustrating a capacitor in a semiconductor device according to a second comparative embodiment;

FIG. 7 is a characteristic diagram illustrating the relationship between the voltage applied to the capacitor in the semiconductor device according to the second comparative embodiment and the capacitance of the capacitor at different frequencies;

FIG. 8 is a characteristic diagram illustrating the relationship between the voltage applied to the capacitor and the capacitance of the capacitor at an operating frequency of 10 GHz in each of the semiconductor devices according to the first embodiment and the second comparative embodiment;

FIG. 9 is a characteristic diagram illustrating the relationship between the voltage applied to the capacitor and the capacitance of the capacitor at an operating frequency of 1 MHz in each of the semiconductor devices according to the first embodiment and the second comparative embodiment;

FIGS. 10A and 10B are cross-sectional views illustrating a production process of a semiconductor device according to a second embodiment;

FIG. 11 is a characteristic diagram illustrating the relationship between the voltage applied to a capacitor in the semiconductor device according to the second embodiment and the capacitance of the capacitor at different frequencies;

FIG. 12 is a cross-sectional view illustrating a capacitor in a semiconductor device according to a third comparative embodiment;

FIG. 13 is a characteristic diagram illustrating the relationship between the voltage applied to the capacitor in the semiconductor device according to the third comparative embodiment and the capacitance of the capacitor at different frequencies;

FIG. 14 is a cross-sectional view illustrating a capacitor in a semiconductor device according to a fourth comparative embodiment;

FIG. 15 is a characteristic diagram illustrating the relationship between the voltage applied to the capacitor in the semiconductor device according to the fourth comparative embodiment and the capacitance of the capacitor at different frequencies;

FIG. 16 is a characteristic diagram illustrating the relationship between the voltage applied to the capacitor and the capacitance of the capacitor at an operating frequency of 10 GHz in each of the semiconductor devices according to the first embodiment and the fourth comparative embodiment; and

FIG. 17 is a characteristic diagram illustrating the relationship between the voltage applied to the capacitor and the capacitance of the capacitor at an operating frequency of 1 MHz in each of the semiconductor devices according to the second embodiment and the fourth comparative embodiment.

### DESCRIPTION OF EMBODIMENTS

The embodiments will be described below with reference to the attached drawings. In the drawings, the same elements are designated using the same reference numerals.

### First Embodiment

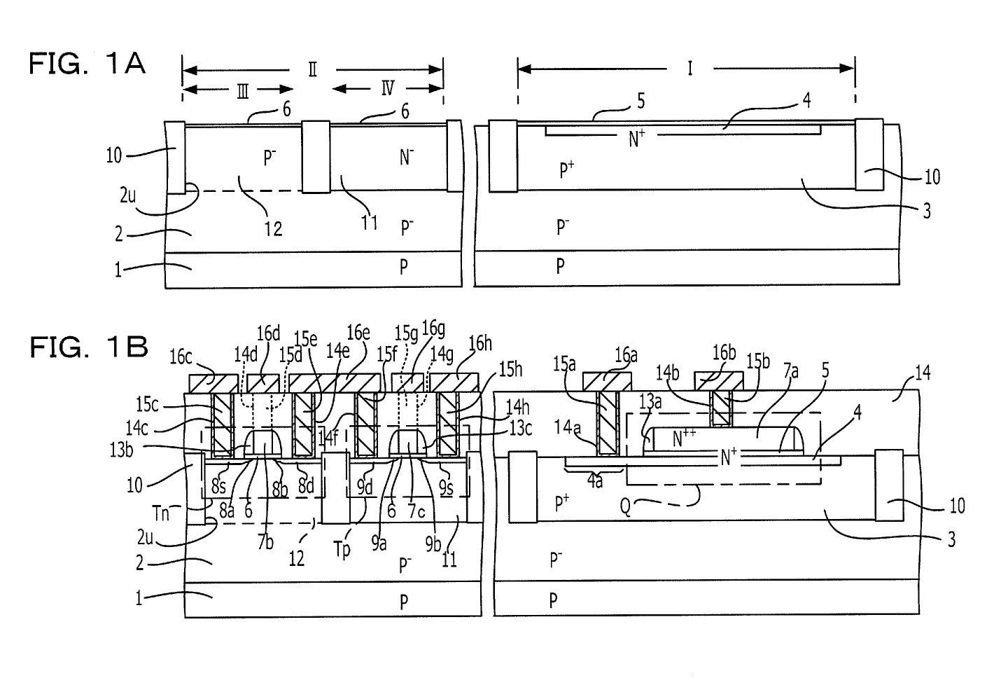

FIGS. 1A and 1B are cross-sectional views illustrating a semiconductor device according to a first embodiment and a process for producing the semiconductor device. Operations of forming a structure illustrated in FIG. 1A will be described below.

In FIG. 1A, a p-type silicon layer 2 with a thickness of about 1.52 μm is formed on a p-type silicon substrate 1. The p-type silicon substrate 1 contains a p-type impurity, such as boron, and has an impurity concentration of about 1.3×10¹⁵ cm⁻³ and an electrical resistivity of about 10 Ωcm. The concentration of the p-type impurity, such as boron, in the p-type silicon layer 2 is higher than the concentration of a p-type impurity in the p-type silicon substrate 1 and is, for example, about 1×10¹⁶ cm⁻³.

The p-type silicon layer 2 is an epitaxially grown p-type semiconductor region with a substantially uniform impurity concentration distribution on the p-type silicon substrate 1. Alternatively, the p-type silicon layer 2 may be a p-type semiconductor region formed by ion implantation of a p-type impurity, such as boron, into the p-type silicon substrate 1.

A silicon oxide film (not illustrated) and a silicon nitride film (not illustrated) are sequentially formed on the p-type silicon layer 2. These films are processed by a photographic method and an etching technique to form openings on element isolation regions and are used as a hard mask (not illustrated). Element isolation trenches 2u are formed in the p-type silicon layer 2 through the openings of the hard mask. Silicon oxide films are formed as insulating films in the element isolation trenches 2u by a chemical vapor deposition (CVD) method to fill the element isolation trenches 2u with the silicon oxide films. A portion of the silicon oxide film on the hard mask is removed by chemical-mechanical polishing. Then the hard mask is removed. The silicon oxide films left in the element isolation trenches 2u are used as shallow trench isolation (STI) regions 10. Each of the STI regions 10 is a type of insulating layer for element isolation. Instead of STI regions 10, insulating layers for element isolation may be formed by local oxidation of silicon (LOCOS).

A p-type impurity, such as boron (B), is ion-implanted into a capacitor formation region I of the p-type silicon layer 2 surrounded by a corresponding one of the STI regions 10. This results in the formation of a p-type impurity diffusion region 3 having a depth of about 0.52 μm from a surface of the p-type silicon layer 2 and having a higher p-type impurity concentration than the p-type silicon layer 2. For example, the p-type impurity diffusion region 3 has a p-type impurity concentration of 5×10¹⁸ cm⁻³ to 5×10¹⁹ cm⁻³, which is two orders of magnitude higher than that of the p-type silicon layer 2. Note that when the p-type impurity is ion-implanted, a region other than the capacitor formation region I is covered with, for example, a photoresist (not illustrated).

An n-type impurity, such as phosphorus (P), is ion-implanted into a portion of the p-type impurity diffusion region 3. This results in the formation of an n-type impurity diffusion region 4 having a junction depth of about 20 nm from a surface of the p-type impurity diffusion region 3 and having an impurity concentration of, for example, 1×10¹⁹ cm⁻³ to 5×10²⁰ cm⁻³. The n-type impurity diffusion region 4 is formed so as to be larger than an upper electrode 7a described below. Note that when the n-type impurity is ion-implanted, a region other than a region to be formed into the n-type impurity diffusion region 4 is covered with, for example, a photoresist (not illustrated).

A silicon oxide film serving as a dielectric film 5 having a thickness of 2 nm is formed on a surface of the n-type impurity diffusion region 4. The dielectric film 5 is formed by, for example, thermal oxidation of the surfaces of the p-type silicon layer 2, the p-type impurity diffusion region 3, and the n-type impurity diffusion region 4.

Before the formation of the dielectric film 5, in the n- and p-type MOS transistor formation subregions III and IV divided by a corresponding one of the STI 10 regions in a complementary metal-oxide semiconductor (CMOS) formation region II, an n-type impurity is ion-implanted into the p-type MOS transistor formation subregion IV to form an N well 11. The N well 11 has an n-type impurity concentration of, for example, about 2×10¹⁶ cm⁻³. Note that when the n-type impurity is ion-implanted, a region other than the p-type MOS transistor formation subregion IV is covered with a photoresist (not illustrated). The n-type MOS transistor formation subregion III of the p-type silicon layer 2 is used as a P well 12. A p-type impurity may be ion-implanted into the n-type MOS transistor formation subregion III of the p-type silicon layer 2 to increase the p-type impurity concentration of the P well 12. A difference in p-type impurity concentration between the P well 12 and the p-type silicon layer 2 may be within an order of magnitude.

Gate insulating films 6 are formed on a surface of the CMOS formation region II of the p-type silicon layer 2. The gate insulating films 6 are formed by, for example, thermal oxidation of the surface of the p-type silicon layer 2. To form the gate insulating films 6 each having the same thickness as the dielectric film 5, the dielectric film 5 and the gate insulating films 6 are simultaneously formed.

To form the gate insulating films 6 and the dielectric film 5 that have different thicknesses, for example, silicon oxide films are first formed by thermal oxidation in both the capacitor formation region I and the CMOS formation region II in response to the thickness of the thinner of the gate insulating film 6 and the dielectric film 5. Then thermal oxidation is further performed to increase the thickness of the silicon oxide films in the other region while one region including the thinner of the gate insulating film 6 and the dielectric film 5 is covered with a resist.

Operations of forming a structure illustrated in FIG. 1B will be described below.

A polysilicon film is formed by a CVD method on the dielectric film 5 and the gate insulating films 6. The resulting polysilicon film is patterned by a photolithographic method and an etching technique. This results in the formation of the upper electrode 7a formed of the patterned polysilicon film in the capacitor formation region I of the p-type silicon layer 2, a first gate electrode 7b formed of the patterned polysilicon film in the n-type MOS transistor formation region III, and a second gate electrode 7c formed of the patterned polysilicon film in the p-type MOS transistor formation region IV.

The upper electrode 7a, the dielectric film 5, and the n-type impurity diffusion region 4, which are located below the upper electrode 7a, in the capacitor formation region I form a capacitor Q. The n-type impurity diffusion region 4 functions as a lower electrode of the capacitor Q. A portion of the n-type impurity diffusion region 4 extending to a side of the upper electrode 7a serves as a contact region 4a. The capacitor Q is used as, for example, a decoupling capacitor. Next, extension regions 8a, 8b, 9a, and 9b of MOS transistors are formed in the p-type silicon layer 2 by a method described below.

A resist pattern (not illustrated) is formed on the p-type silicon layer 2, thereby covering the p-type MOS transistor formation subregion IV and the capacitor formation region I and exposing the n-type MOS transistor formation subregion III. An n-type impurity, such as phosphorus, is ion-implanted into the P well 12 to form the n-type extension regions 8a and 8b on the respective sides of the first gate electrode 7b. In this case, each of the n-type extension regions 8a and 8b has an n-type impurity concentration of, for example, about 5×10¹⁸ cm⁻³. Then the resist pattern (not illustrated) is removed.

A resist pattern (not illustrated) is formed on the p-type silicon layer 2 so as to cover the n-type MOS transistor formation subregion III and the capacitor formation region I and to expose the p-type MOS transistor formation subregion IV. A p-type impurity, such as boron, is ion-implanted into the N well 11 to form the p-type extension regions 9a and 9b on the respective sides of the second gate electrode 7c. Each of the p-type extension regions 9a and 9b has a p-type impurity concentration of, for example, about 5×10¹⁸ cm⁻³. Then the resist pattern (not illustrated) is removed.

A silicon oxide film serving as an insulating film is formed by a CVD method on the p-type silicon layer 2, the first and second gate electrodes 7b and 7c, and the upper electrode 7a and is etched back. Portions of the silicon oxide films left on side walls of each of the first and second gate electrodes 7b and 7c and the upper electrode 7a are used as insulating side walls 13a, 13b, and 13c. Then source and drain regions 8s, 8d, 9s, and 9d of the MOS transistors are formed by a method described below.

A resist pattern (not illustrated) is formed on the p-type silicon layer 2 so as to cover the p-type MOS transistor formation subregion IV and expose the upper electrode 7a in the capacitor formation region I and the n-type MOS transistor formation subregion III. An n-type impurity is ion-implanted into the P well 12 with the first gate electrode 7b and its surrounding side wall 13b, which serve as a mask, to form the n-type source and drain regions 8s and 8d. Each of the n-type source and drain regions 8s and 8d has an n-type impurity concentration of, for example, about 1×10²⁰ cm⁻³.

In this case, the n-type impurity is also ion-implanted into the polysilicon films serving as the first gate electrode 7b and the upper electrode 7a. Each of the polysilicon films has an n-type impurity concentration of about 1×10²⁰ cm⁻³. The n-type impurity concentration of the upper electrode 7a is higher than that of the n-type impurity diffusion region 4 located below the upper electrode 7a. Here, an n-type impurity may be ion-implanted into the contact region 4a of the n-type impurity diffusion region 4 to increase the impurity concentration.

The first gate electrode 7b, a corresponding one of the gate insulating films 6, the n-type source and drain regions 8s and 8d, the P well 12, and so forth form an n-type MOS transistor Tn. Then the resist pattern (not illustrated) on the p-type silicon layer 2 is removed.

A resist pattern (not illustrated) is formed on the p-type silicon layer 2 so as to cover the n-type MOS transistor formation subregion III and the capacitor formation region I and to expose the p-type MOS transistor formation subregion IV. A p-type impurity is ion-implanted into the N well 11 with the second gate electrode 7c and its surrounding side wall 13c, which serve as a mask, to form the p-type source and drain regions 9s and 9d in the N well 11. Each of the p-type source and drain regions 9s and 9d has a p-type impurity concentration of, for example, about 1×10²⁰ cm⁻³. In this case, the p-type impurity is also ion-implanted into the polysilicon film serving as the second gate electrode 7c, so that the polysilicon film has a p-type impurity concentration of about 1×10²⁰ cm⁻³.

The second gate electrode 7c, a corresponding one of the gate insulating films 6, the p-type source and drain regions 9s and 9d, the N well 11, and so forth form a p-type MOS transistor Tp. Then the resist pattern (not illustrated) on the p-type silicon layer 2 is removed.

An interlayer insulating film 14 arranged to cover the p-type MOS transistor Tp, the n-type MOS transistor Tn, and the capacitor Q is formed on the p-type silicon layer 2. Then the upper surface of the interlayer insulating film 14 is polished and planarized by CMP. The interlayer insulating film 14 is patterned by the photolithographic method and the etching technique. This results in the formation of contact holes 14a to 14h on the first and second gate electrodes 7b and 7c, the n-type source and drain regions 8s and 8d, the p-type source and drain regions 9s and 9d, the dielectric film 5, and the contact region 4a of the n-type impurity diffusion region 4. Conductive plugs 15a to 15h are formed in the contact holes 14a to 14h. A conductive film is formed on the interlayer insulating film 14. The conductive film is patterned to form interconnections 16a to 16e, 16g, and 16h.

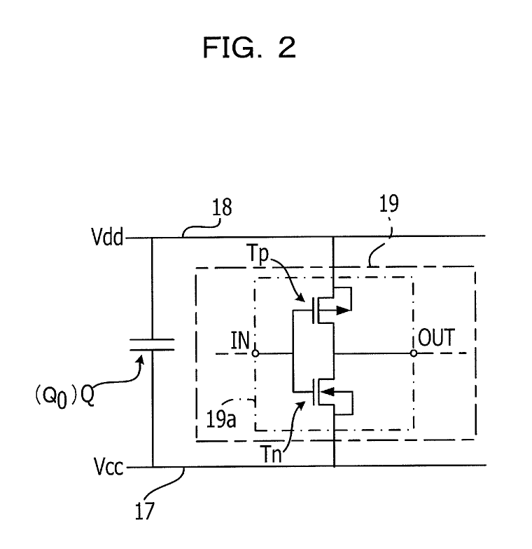

The interconnections 16a to 16e, 16g, and 16h electrically connected to the p-type MOS transistor Tp, the n-type MOS transistor Tn, and the capacitor Q through the conductive plugs 15a to 15h are connected to a pair of power lines 17 and 18 as illustrated in an equivalent circuit diagram of FIG. 2. The p-type MOS transistor Tp and the n-type MOS transistor Tn are connected to each other with the interconnections 16c to 16e, 16g, and 16h through the conductive plugs 15c to 15h to form a CMOS 19a in a logic circuit 19.

For example, a positive voltage Vdd is applied to the positive second power line 18. A voltage Vcc, such as a ground voltage, is applied to the first power line 17. The first power line 17 is connected to the contact region 4a of the n-type impurity diffusion region 4 through the interconnection 16a and the conductive plug 15a. The second power line 18 is connected to the upper electrode 7a through the interconnection 16b and the conductive plug 15b. The p-type silicon layer 2 is set so as to have the same potential as the n-type impurity diffusion region 4.

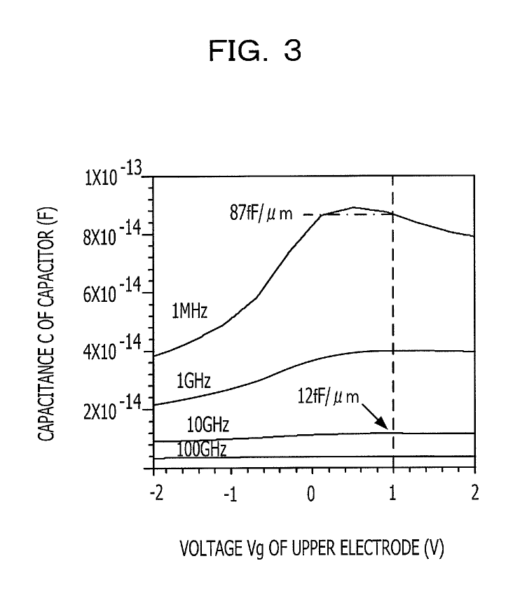

For the capacitor Q having the foregoing structure, the potential difference of the upper electrode 7a with respect to the n-type impurity diffusion region 4 is set to Vg. Frequencies of signals applied to an input port IN of the CMOS 19a are set to 1 MHz, 1 GHz, 10 GHz, and 100 GHz. A change in the capacitance of the capacitor Q against the potential difference Vg is studied. FIG. 3 illustrates the results. Note that FIG. 3 illustrates the results analyzed by Sentaurus Device, which is a device simulator. FIG. 3 demonstrates that the capacitor Q has a capacitance of 12 fF/μm at 10 GHz when Vg is 1 V.

Two comparative embodiments each different from the first embodiment in structure will be described below.

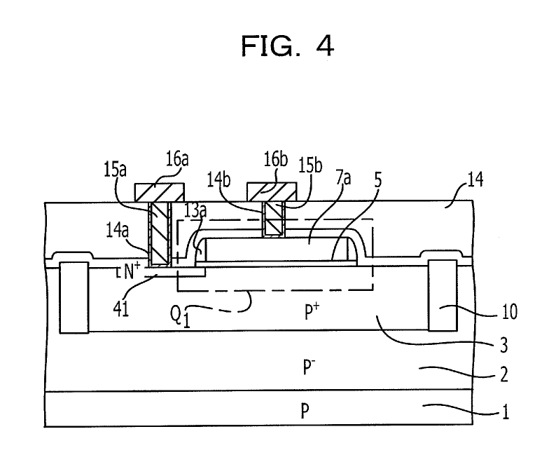

A capacitor Q₁ according to a first comparative embodiment has a structure illustrated in FIG. 4 and an n-type MOS structure.

As with the capacitor Q according to the first embodiment, the capacitor Q₁ illustrated in FIG. 4 includes the p-type silicon layer 2 on the p-type silicon substrate 1. The p-type impurity diffusion region 3 having a depth of about 0.52 μm from the surface of the p-type silicon layer 2 is provided in the p-type silicon layer 2. The upper electrode 7a is provided on the p-type impurity diffusion region 3 via the dielectric film 5 having a thickness of 2 nm. An n-type impurity diffusion region 41 serving as a contact region and having a junction depth of about 20 nm from a surface of the p-type impurity diffusion region 3 is provided in the p-type impurity diffusion region 3 and located on a side of the upper electrode 7a.

The p-type impurity diffusion region 3 has an impurity concentration of about 5×10¹⁸ cm⁻³. The n-type impurity diffusion region 41 has an impurity concentration of about 5×10¹⁹ cm⁻³. The impurity concentrations of the p-type silicon substrate 1, the p-type silicon layer 2, the upper electrode 7a, and other elements are equal to those of the first embodiment.

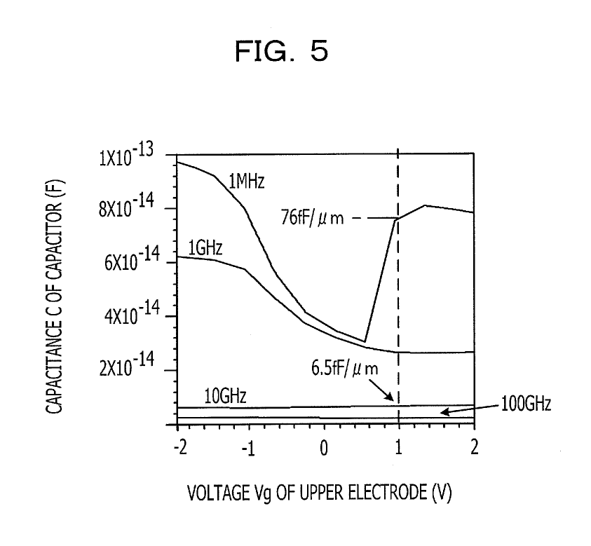

The capacitor Q₁ having the structure illustrated in FIG. 4 is connected to the first and second power lines 17 and 18 illustrated in FIG. 2. The potential difference of the upper electrode 7a with respect to the n-type impurity diffusion region 41 is set to Vg. A change in the capacitance of the capacitor Q₁ against the potential difference Vg is studied at different frequencies of signals applied to the input port of the CMOS 19a. FIG. 5 illustrates the results. Note that FIG. 5 illustrates the results analyzed by Sentaurus Device, which is a device simulator. FIG. 5 demonstrates that the capacitor Q₁ according to the first comparative embodiment has a capacitance of 6.5 fF/μm at an operating frequency of 10 GHz when the potential difference Vg is 1 V. Thus, the capacitance of the capacitor Q according to the first embodiment is about 1.9 times that of the capacitor Q₁ according to the first comparative embodiment at 10 GHz.

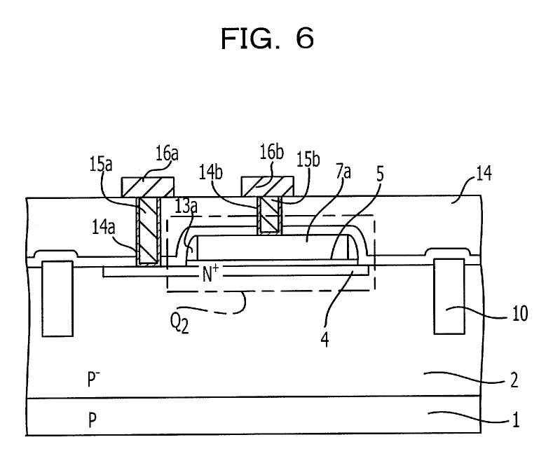

A capacitor Q₂ according to a second comparative embodiment has a structure as illustrated in FIG. 6. The capacitor Q₂ has the same structure as the capacitor Q according to the first embodiment as illustrated in FIG. 1, except that the p-type impurity diffusion region 3 is not provided. In FIG. 6, the same reference numerals as those in FIG. 1 indicate the same elements in FIG. 1. These elements in FIG. 6 are adjusted to have the same impurity concentrations as in the first embodiment.

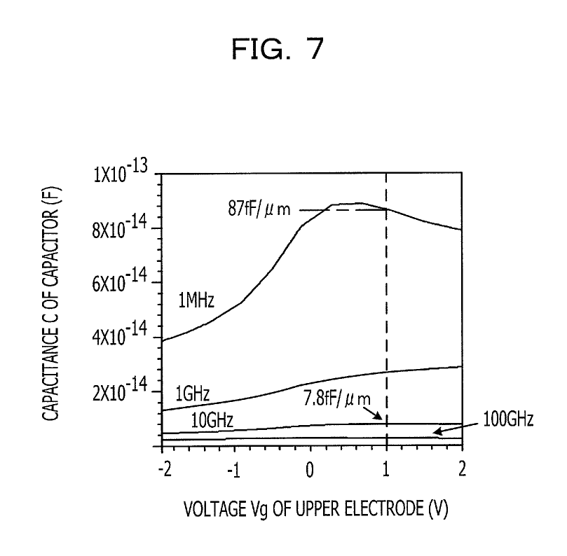

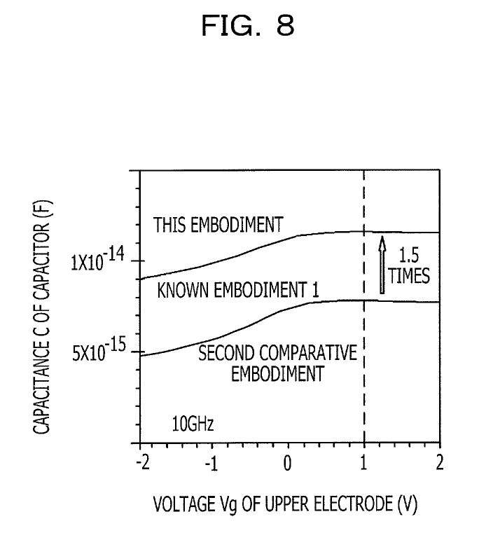

The capacitor Q₂ having the structure illustrated in FIG. 6 is connected to the first and second power lines 17 and 18 illustrated in FIG. 2. The potential difference of the upper electrode 7a with respect to the n-type impurity diffusion region 4 is set to Vg. A change in the capacitance of the capacitor Q₂ against the potential difference Vg is studied at different operating frequencies of the logic circuit 19 illustrated in FIG. 2. FIG. 7 illustrates the results. Note that FIG. 7 illustrates the results analyzed by Sentaurus Device, which is a device simulator. FIG. 7 demonstrates that the capacitor Q₂ has a capacitance of 7.8 fF/μm at 10 GHz. Thus, the capacitance of the capacitor Q according to the first embodiment is about 1.5 times that of the capacitor Q₂ illustrated in FIG. 6 at 10 GHz, as illustrated in FIG. 8.

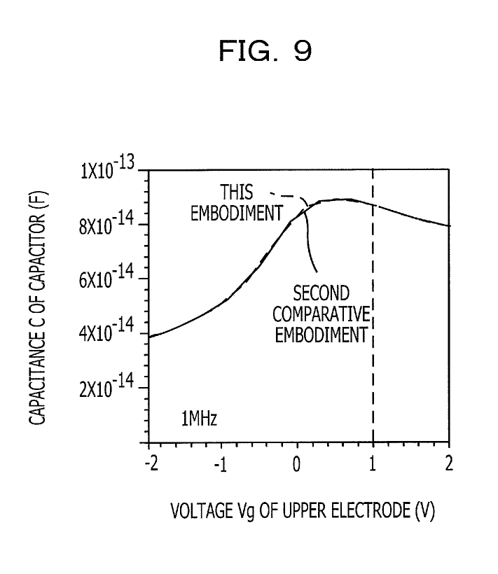

For each of the capacitor Q₂ according to the second comparative embodiment and the capacitor Q according to the first embodiment, when the frequency of a signal applied to the logic circuit 19 is 1 MHz, the relationship between the voltage of the upper electrode 7a and the capacitance of each capacitor is simulated. FIG. 9 illustrates the results. FIG. 9 demonstrates that the capacitors Q and Q₂ have substantially the same characteristics.

The difference in structure between the capacitor Q according to the first embodiment and the capacitor Q₂ according to the second comparative embodiment is whether the p-type impurity diffusion region 3 having a higher p-type impurity concentration than the p-type silicon layer 2 is present or not. The difference as illustrated in FIG. 8 due to the structural difference appears to be due to the following reason.

That is, in an energy band structure, the built-in potential of the boundary between the p-type impurity diffusion region 3 having a high impurity concentration and the n-type impurity diffusion region 4 is higher than the built-in potential of the boundary between the p-type silicon layer 2 and the n-type impurity diffusion region 4. Electrons serving as majority carriers in the n-type impurity diffusion region 4 seem to extend as the frequency of an operating frequency component applied to a power source voltage (Vdd-Vcc) increases. Thus, the electrons in the n-type impurity diffusion region 4 are less likely to diffuse in the p-type impurity regions as the p-type impurity concentrations in the p-type impurity semiconductor regions (2 and 3) joined to the n-type impurity diffusion region 4 increase. Accordingly, in the capacitor Q according to the first embodiment, the n-type impurity diffusion region 4 may have a high electron density at a high frequency. Thus, the capacitor Q has a higher capacitance than the capacitor Q₂ according to the second comparative embodiment, thereby inhibiting voltage fluctuations in a high-frequency band.

Referring to FIGS. 3, 5, and 7 to 9, when the voltage Vg of the upper electrode 7a is negative with respect to the n-type impurity diffusion region 4, the capacitance of the capacitor is reduced. The reason for this is believed that the application of a positive potential to the n-type impurity diffusion region 4 reduces the majority carriers, increases holes serving as minority carriers, and extends a depletion region, thereby resulting in weak confinement of electrons in the n-type impurity diffusion region 4.

### Second Embodiment

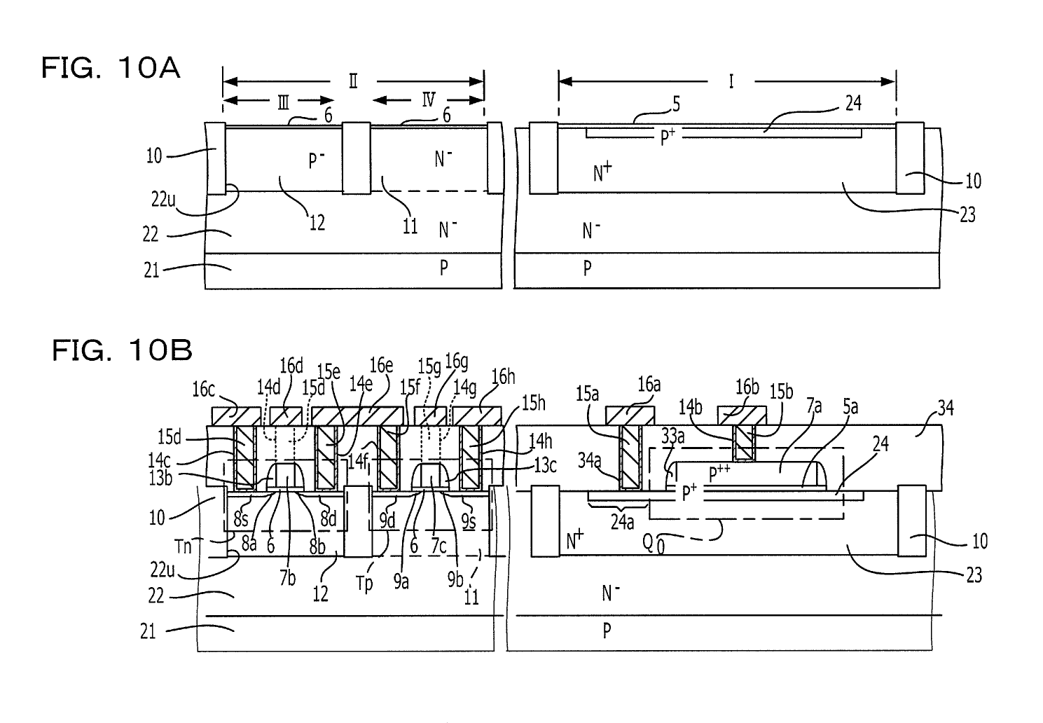

FIGS. 10A and 10B are cross-sectional views illustrating a semiconductor device according to a second embodiment and a process for producing the semiconductor device. In FIGS. 10A and 10B, the same reference numerals as those in FIG. 1 represent the same elements as those in FIG. 1. Operations of forming a structure illustrated in FIG. 10A will be described below.

In FIG. 10A, an n-type silicon layer 22 having a depth of about 1.52 μm is formed on a p-type silicon substrate 21. The p-type silicon substrate 21 contains a p-type impurity, such as boron, and has an impurity concentration of about 1.3×10¹⁵ cm⁻³ and an electrical resistivity of about 10 Ωcm. The concentration of the n-type impurity, such as phosphorus, in the n-type silicon layer 22 is adjusted to, for example, about 1×10¹⁶ cm⁻³.

The n-type silicon layer 22 is an n-type impurity semiconductor region epitaxially grown on the p-type silicon substrate 21. Alternatively, the n-type silicon layer 22 may be an n-type impurity semiconductor region formed by ion implantation of an n-type impurity, such as phosphorus, into the p-type silicon substrate 1.

As with the first embodiment, for example, the STI 10 regions serving as insulating layers for element isolation are formed in the n-type silicon layer 22. Then an n-type impurity, such as phosphorus, is ion-implanted into the capacitor formation region I of the n-type silicon layer 22. This results in the formation of an n-type impurity diffusion region 23 having a depth of about 0.52 μm from a surface of the n-type silicon layer 22 and having a higher impurity concentration than the n-type silicon layer 22. For example, the n-type impurity diffusion region 23 has an impurity concentration of 5×10¹⁸ cm⁻³ to 5×10¹⁹ cm⁻³, which is two orders of magnitude higher than that of the n-type silicon layer 22. Note that when the n-type impurity is ion-implanted, a region other than the capacitor formation region I is covered with, for example, a photoresist (not illustrated).

A p-type impurity, such as boron, is ion-implanted into a portion of the n-type impurity diffusion region 23. This results in the formation of a p-type impurity diffusion region 24 having a junction depth of about 20 nm from a surface of the n-type impurity diffusion region 23 and having an impurity concentration of, for example, 1×10¹⁹ cm⁻³ to 5×10²⁰ cm⁻³. The p-type impurity diffusion region 24 is formed so as to be larger than the upper electrode 7a. Note that when the p-type impurity is ion-implanted, a region other than a region to be formed into the p-type impurity diffusion region 24 is covered with, for example, a photoresist (not illustrated).

A silicon oxide film serving as the dielectric film 5 having a thickness of 2 nm is formed on a surface of the p-type impurity diffusion region 24. The dielectric film 5 is formed by, for example, thermal oxidation of the surfaces of the n-type silicon layer 22, the n-type impurity diffusion region 23, and the p-type impurity diffusion region 24.

Before the formation of the dielectric film 5, in the n- and p-type MOS transistor formation subregions III and IV divided by a corresponding one of the STI 10 regions in the CMOS formation region II, a p-type impurity is ion-implanted into the n-type silicon layer 22 in the n-type MOS transistor formation subregion III to form the P well 12. The P well 12 has a p-type impurity concentration of, for example, about 2×10¹⁶ cm⁻³. Note that when the p-type impurity is ion-implanted, a region other than the n-type MOS transistor formation subregion III is covered with a photoresist (not illustrated).

The p-type MOS transistor formation subregion IV of the n-type silicon layer 22 is used as the N well 11. In this case, an n-type impurity may be ion-implanted into the p-type MOS transistor formation subregion IV of the n-type silicon layer 22 to increase the n-type impurity concentration of the N well 11. A difference in n-type impurity concentration between the N well 11 and the n-type silicon layer 22 may be within an order of magnitude.

The gate insulating films 6 are formed on a surface of the CMOS formation region II of the n-type silicon layer 22. The gate insulating films 6 are formed by, for example, thermal oxidation of the surface of the n-type silicon layer 22. Thicknesses of the gate insulating films 6 and the dielectric film 5 are adjusted in the same way as in the first embodiment.

Operations of forming a structure illustrated in FIG. 10B will be described below.

The upper electrode 7a and the first and second gate electrodes 7b and 7c each constituted by polysilicon films are formed on the dielectric film 5 and the gate insulating films 6 in the same way as in the first embodiment.

Thereby, the upper electrode 7a, the dielectric film 5 below the upper electrode 7a, and the p-type impurity diffusion region 24 form a capacitor Q₀ in the capacitor formation region I. The p-type impurity diffusion region 24 functions as a lower electrode of the capacitor Q₀. A portion of the p-type impurity diffusion region 24 extending to a side of the upper electrode 7a serves as a contact region 24a. The capacitor Q₀ is used as, for example, a decoupling capacitor.

The n-type extension regions 8a and 8b of an n-type MOS transistor are formed in the P well 12, and the p-type extension regions 9a and 9b of an p-type MOS transistor are formed in the N well 11, in the same way as in the first embodiment. Each of the n-type extension regions 8a and 8b has an n-type impurity concentration of, for example, about 5×10¹⁸ cm⁻³. Each of the p-type extension regions 9a and 9b has a p-type impurity concentration of, for example, about 5×10¹⁸ cm⁻³.

The insulating side walls 13a, 13b, and 13c are formed on side walls of the first and second gate electrodes 7b and 7c and the upper electrode 7a in the same way as in the first embodiment. The n-type source and drain regions 8s and 8d of the n-type MOS transistor are formed in the P well 12, and the p-type source and drain regions 9s and 9d of the p-type MOS transistor are formed in the N well 11, in the same way as in the first embodiment. Each of the n-type source and drain regions 8s and 8d has an n-type impurity concentration of, for example, about 1×10²⁰ cm⁻³. Each of the p-type source and drain regions 9s and 9d has a p-type impurity concentration of, for example, about 1×10²⁰ cm⁻³.

In this case, the p-type impurity is also ion-implanted into the polysilicon films serving as the second gate electrode 7c and the upper electrode 7a, so that each of the polysilicon films has a p-type impurity concentration of, for example, about 1×10²⁰ cm⁻³. The upper electrode 7a has a higher p-type impurity concentration than the p-type impurity diffusion region 24 located below the upper electrode 7a. When the p-type source and drain regions 9s and 9d are formed, a p-type impurity may be ion-implanted into the contact region 24a of the p-type impurity diffusion region 24 to increase the impurity concentration. The polysilicon film serving as the first gate electrode 7b has an n-type impurity concentration of, for example, about 1×10²⁰ cm⁻³.

The first gate electrode 7b, the gate insulating films 6, the n-type source and drain regions 8s and 8d, the P well 12 and so forth form the n-type MOS transistor Tn. The second gate electrode 7c, the gate insulating films 6, the p-type source and drain regions 9s and 9d, the N well 11, and so forth form the p-type MOS transistor Tp.

The interlayer insulating film 14 arranged to cover the p-type MOS transistor Tp, the n-type MOS transistor Tn, and the capacitor Q₀ is formed in the same way as in the first embodiment. The contact holes 14a to 14h are formed. The conductive plugs 15a to 15h are formed in the contact holes 14a to 14h. The interconnections 16a to 16e, 16g, and 16h are formed on the interlayer insulating film 14.

The interconnections 16a to 16e, 16g, and 16h electrically connected to the p-type MOS transistor Tp, the n-type MOS transistor Tn, and the capacitor Q₀ through the conductive plugs 15a to 15h are connected to the pair of power lines 17 and 18 as illustrated in the equivalent circuit diagram of FIG. 2. The p-type MOS transistor Tp and the n-type MOS transistor Tn are connected to each other with the interconnections 16c to 16e, 16g, and 16h through the conductive plugs 15c to 15h to form the CMOS 19a in the logic circuit 19.

A voltage Vdd is applied to the second power line 18. A voltage Vcc is applied to the first power line 17. The second power line 18 is connected to the contact region 24a of the p-type impurity diffusion region 24 through the interconnection 16a and the conductive plug 15a. The first power line 17 is connected to the upper electrode 7a through the interconnection 16b and the conductive plug 15b. The n-type silicon layer 22 is set so as to have the same potential as the p-type impurity diffusion region 24.

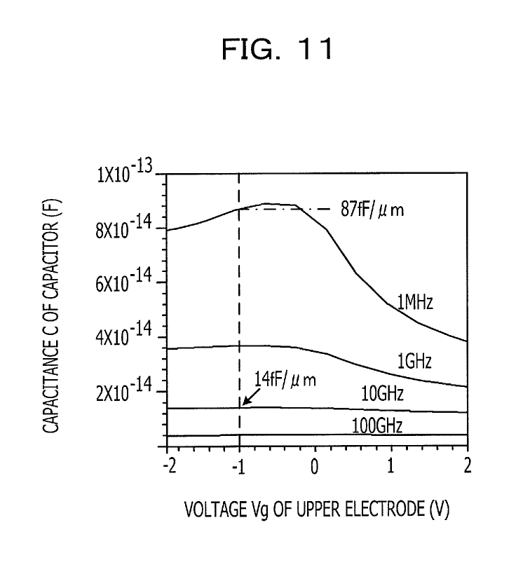

For the Q₀ having the foregoing structure, the potential difference of the upper electrode 7a with respect to the p-type impurity diffusion region 24 is set to Vg. Frequencies of signals applied to the input port of the CMOS 19a are set to 1 MHz, 1 GHz, 10 GHz, and 100 GHz. A change in the capacitance of the capacitor Q₀ against the potential difference Vg is studied. FIG. 11 illustrates the results. Note that FIG. 11 illustrates the results analyzed by Sentaurus Device, which is a device simulator. FIG. 11 demonstrates that the capacitor Q₀ has a capacitance of 14 fF/μm at 10 GHz when Vg is −1 V.

Two comparative embodiments each different from the second embodiment in structure will be described below.

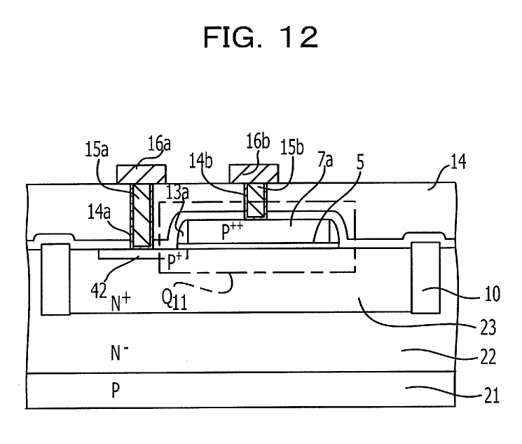

A capacitor Q₁₁ according to a third comparative embodiment has a structure illustrated in FIG. 12 and a p-type MOS structure.

As with the capacitor Q₀ according to the second embodiment, the capacitor Q₁₁ illustrated in FIG. 12 includes the n-type silicon layer 22 on the p-type silicon substrate 21. The n-type impurity diffusion region 23 having a depth of about 0.52 μm from the surface of the n-type silicon layer 22 is provided in the n-type silicon layer 22. The upper electrode 7a is provided on the n-type impurity diffusion region 23 via the dielectric film 5 having a thickness of 2 nm. A p-type impurity diffusion region 42 serving as a contact region and having a junction depth of about 20 nm from a surface of the n-type impurity diffusion region 23 is provided in the n-type impurity diffusion region 23 and located on a side of the upper electrode 7a.

The n-type silicon layer 22 has an impurity concentration of about 5×10¹⁸ cm⁻³. The p-type impurity diffusion region 42 has an impurity concentration of about 5×10¹⁹ cm⁻³. The impurity concentrations of the p-type silicon substrate 21, the n-type silicon layer 22, the upper electrode 7a, and other elements are equal to those of the second embodiment.

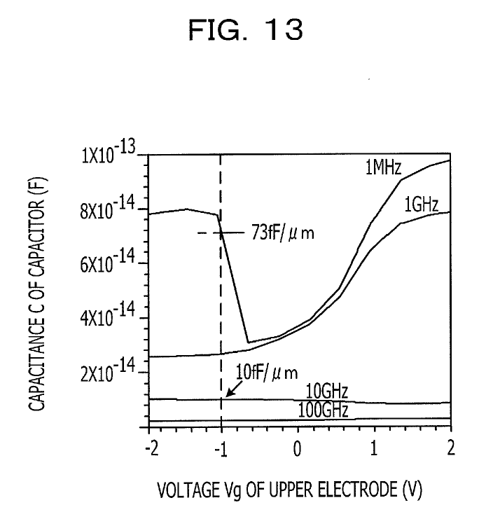

The potential difference of the upper electrode 7a with respect to the p-type impurity diffusion region 42 of the capacitor Q₁₁ having the structure illustrated in FIG. 12 is set to Vg. A change in the capacitance of the capacitor Q₁₁ against the potential difference Vg is studied at different frequencies of signals applied to the input port IN of the CMOS 19a. FIG. 13 illustrates the results. Note that FIG. 13 illustrates the results analyzed by Sentaurus Device, which is a device simulator. FIG. 13 demonstrates that the capacitor Q₁₁ according to the third comparative embodiment has a capacitance of 10 fF/μm at an operating frequency of 10 GHz when the potential difference Vg is −1 V. Thus, the capacitance of the capacitor Q₀ according to the second embodiment is about 1.4 times that of the capacitor Q₁₁ according to the third comparative embodiment at 10 GHz.

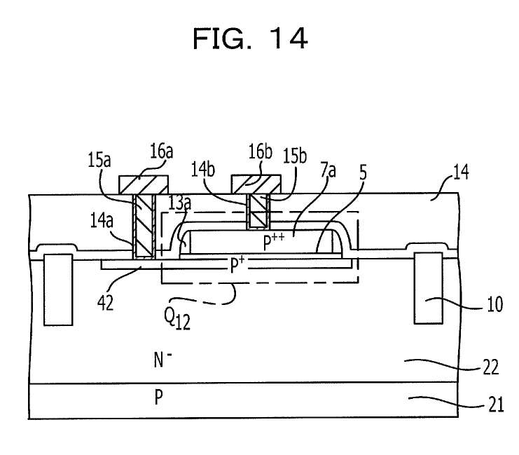

A capacitor Q₁₂ according to a fourth comparative embodiment has a structure as illustrated in FIG. 14. The capacitor Q₁₂ has the same structure as the capacitor Q₀ according to the second embodiment as illustrated in FIG. 10, except that the n-type impurity diffusion region 23 is not provided. In FIG. 14, the same reference numerals as those in FIG. 10 indicate the same elements in FIG. 10. These elements in FIG. 10 are adjusted to have the same impurity concentrations as in the second embodiment.

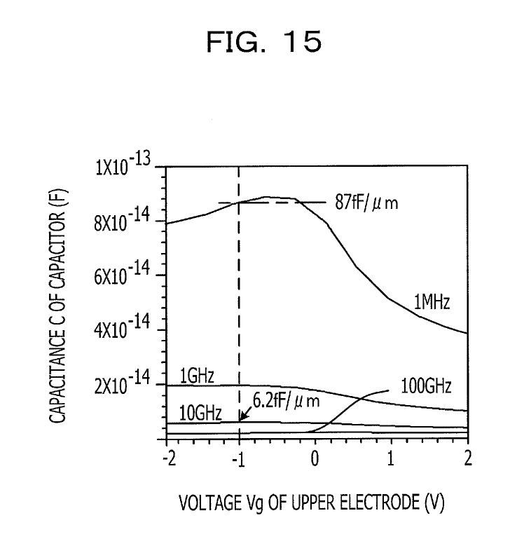

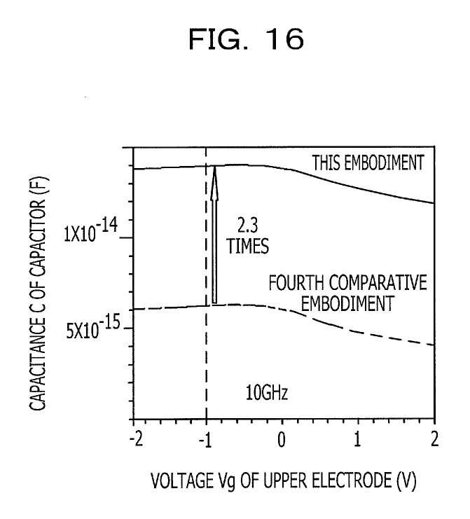

The potential difference of the capacitor Q₁₂ having the structure illustrated in FIG. 14 with respect to the p-type impurity diffusion region 24 is set to Vg. A change in the capacitance of the capacitor Q₁₂ against the potential difference Vg is studied at different operating frequencies of signals applied to the input port IN of the CMOS 19a illustrated in FIG. 2. FIG. 15 illustrates the results. Note that FIG. 15 illustrates the results analyzed by Sentaurus Device, which is a device simulator. FIG. 15 demonstrates that the capacitor Q₁₂ has a capacitance of 6.2 fF/μm at 10 GHz. Thus, as illustrated in FIG. 16, the capacitance of the capacitor Q₀ according to the second embodiment is about 2.3 times that of the capacitor Q₁₂ illustrated in FIG. 14.

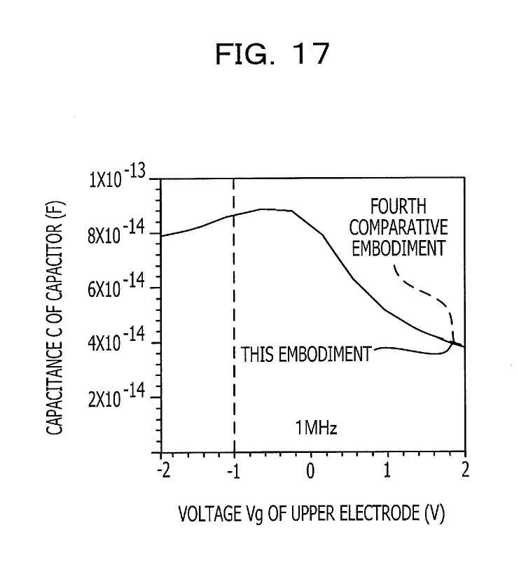

For each of the capacitor Q₁₂ according to the fourth comparative embodiment and the capacitor Q₀ according to the second embodiment, when the frequency of a signal applied to the logic circuit 19 is 1 MHz, the relationship between the voltage of the upper electrode 7a and the capacitance of each capacitor is simulated. FIG. 17 illustrates the results. FIG. 17 demonstrates that the capacitors Q₀ and Q₁₂ have substantially the same characteristics.

The difference in structure between the capacitor Q₀ according to the second embodiment and the capacitor Q₁₂ according to the fourth comparative embodiment is whether the n-type impurity diffusion region 23 having a higher n-type impurity concentration than the n-type silicon layer 22 is present or not. The difference as illustrated in FIG. 16 due to the structural difference appears to be due to the following reason.

That is, in an energy band structure, the built-in potential of the boundary between the n-type impurity diffusion region 23 having a high impurity concentration and the p-type impurity diffusion region 24 is higher than the built-in potential of the boundary between the n-type silicon layer 22 and the p-type impurity diffusion region 24. Holes serving as majority carriers in the p-type impurity diffusion region 24 seem to diffuse as the frequency of an operating frequency component applied to a power source voltage (Vdd-Vcc) increases. Thus, the holes in the p-type impurity diffusion region 24 are less likely to diffuse as the n-type impurity concentrations in the n-type impurity semiconductor regions (22 and 23) joined to the p-type impurity diffusion region 24 increase. Accordingly, in the capacitor Q₀ according to the second embodiment, the p-type impurity diffusion region 24 may have a high hole density at a high frequency. Thus, the capacitor Q₀ has a higher capacitance than the capacitor Q₁₂ according to the fourth comparative embodiment, thereby inhibiting voltage fluctuations in a high-frequency band.

Referring to FIGS. 11, 13, and 15, when the voltage Vg of the upper electrode 7a is positive with respect to the p-type impurity diffusion region 24, the capacitance of the capacitor is reduced. The reason for this is believed that the application of a negative potential to the p-type impurity diffusion region 24 reduces the majority carriers, increases electrons serving as minority carriers, and extends a depletion region, thereby resulting in weak confinement of holes in the p-type impurity diffusion region 24.

In the foregoing embodiments, the silicon substrate 1 is used as a semiconductor substrate. Alternatively, an SOI substrate may be used. The silicon substrate 1 may be an n- or p-type substrate. The n-type impurity is one or the other of a first conductivity type impurity and &second conductivity type impurity. The p-type impurity is the other impurity.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a semiconductor circuit; and
a capacitor including:
a first semiconductor region of a first conductivity type,
a second semiconductor region of the first conductivity type, the second semiconductor region being provided on the first semiconductor region of the first conductivity type and having a higher concentration of a first conductivity type impurity than the first semiconductor region of the first conductivity type,
a semiconductor region of a second conductivity type provided on the second semiconductor region of the first conductivity type,
a dielectric film provided on the semiconductor region of the second conductivity type,
an upper electrode provided on the dielectric film,
a first interconnection provided above the semiconductor region of the second conductivity type and electrically connected to the semiconductor region of the second conductivity type, and
a second interconnection electrically connected to the upper electrode.

2. The semiconductor device according to claim 1, wherein
the upper electrode is formed of a semiconductor film of the second conductivity type, the upper electrode having a higher concentration of a second conductivity type impurity than the semiconductor region of the second conductivity type.

3. The semiconductor device according to claim 1, wherein
the semiconductor circuit includes
a complementary metal oxide semiconductor (CMOS) in which a metal-oxide semiconductor (MOS) transistor of the first conductivity type and a MOS transistor of the second conductivity type are connected to each other,
one of the source and drain regions of the MOS transistor of the first conductivity type is connected to one or the other of the first interconnection and the second interconnection, and
one of the source and drain regions of the MOS transistor of the second conductivity type is connected to one of the other interconnection.

4. The semiconductor device according to claim 1,
wherein the MOS transistor of the second conductivity type is provided in a well of the first conductivity type,
wherein the well of the first conductivity type has the same impurity concentration of the first conductivity type as the first semiconductor region of the first conductivity type, or
a difference in impurity concentration of the first conductivity type between the well of the first conductivity type and the first semiconductor region of the first conductivity type is within an order of magnitude.

5. The semiconductor device according to claim 1, wherein
the first semiconductor region of the first conductivity type is a layer epitaxially grown on a semiconductor substrate of the first conductivity type or the second conductivity type.

6. The semiconductor device according to claim 1, wherein
the semiconductor region of the second conductivity type is an n-type semiconductor region,
the upper electrode is an n-type semiconductor pattern, and
a higher voltage than a voltage applied to the first interconnection is applied to the upper electrode through the second interconnection.

7. The semiconductor device according to claim 1, wherein
the semiconductor region of the second conductivity type is a p-type semiconductor region,
the upper electrode is a p-type semiconductor pattern, and
a higher voltage than a voltage applied to the second interconnection is applied to the semiconductor region of the second conductivity type through the first interconnection.

8. The semiconductor device according to claim 1, wherein
the second semiconductor region of the first conductivity type has a concentration of the first conductivity type impurity of 5×10¹⁸ cm⁻³ to 5×10¹⁹ cm⁻³, and
the semiconductor region of the second conductivity type has a concentration of the second conductivity type impurity of 1×10¹⁹ cm⁻³ to 5×10²⁰ cm⁻³.
